(19) United States
(12) Patent Application Publication
(10) Pub. No.: US 2020/0277512 A1
(43) Pub. Date: Sep. 3, 2020

(54) COMPOSITION FOR FILM DEPOSITION AND FILM DEPOSITION APPARATUS

(71) Applicant: Tokyo Electron Limited, Tokyo (JP)

(72) Inventors: Tatsuya YAMAGUCHI, Yamanashi (JP); Ryuichi ASAKO, Miyagi (JP)

(21) Appl. No.: 16/645,951

(22) PCT Filed: May 24, 2019
(86) PCT No.: PCT/JP2019/020631

§ 371 Date: Mar. 10, 2020

(30) Foreign Application Priority Data
Jun. 5, 2018 (JP) 2018-108154

(51) Int. Cl. C09D 177/04; H01L 21/311; H01L 21/02; B05D 1/00; B05D 1/32

(52) U.S. Cl. CPC C09D 177/04; H01L 21/31144; B05D 1/322; B05D 1/60; H01L 21/02118

(57) ABSTRACT

A composition for film deposition that includes a first component and a second component, wherein the second component polymerizes with the first component to form a nitrogen-containing carbonyl compound, and wherein a molecular structure of the first component and a molecular structure of the second component are asymmetric with each other, is provided.

### TECHNICAL FIELD

The present invention relates to a composition for film deposition and a film deposition apparatus.

### BACKGROUND

In a film deposition process such as vapor deposition polymerization, a molecule supplied with gas is adsorbed on a substrate and polymerized by thermal energy of the substrate, and a thin film of polymer is formed. Patent Document 1 discloses a film deposition method of forming a polyimide film by supplying a first processing gas that includes a first monomer and a second processing gas that includes a second monomer to a substrate, and performing vapor deposition and polymerization of the first monomer and the second monomer on a surface of a wafer.

### CITATION LIST

### Patent Document

### [Patent Document 1] Japanese Patent No. 5966618

### SUMMARY

### Problem to be Solved by the Invention

Crystallization in a film may occur in a polymer film formed by a film deposition process. Such crystallization may reduce the uniformity of a film (hereinafter referred to as film roughness) and cause structural defects.

It is an object of the present invention to provide a composition for film deposition that can suppress the occurrence of crystallization in a film.

### Means for Solving Problem

In order to achieve the object described above, one aspect of the present invention provides a composition for film deposition that includes a first component that polymerizes with a second component to form a nitrogen-containing carbonyl compound, and wherein the molecular structure of the first component and the molecular structure of the second component are asymmetric with each other.

### Effect of Invention

According to one aspect of the present invention, the occurrence of crystallization in a film can be suppressed.

### BRIEF DESCRIPTION OF THE DRAWINGS

FIG. 1 is a cross-sectional view of a film deposition apparatus according to an embodiment of the present invention;

FIG. 2 is a chart illustrating timing of supplying gas in the film deposition apparatus illustrated in FIG. 1;

FIG. 3 is a cross-sectional view of a wafer illustrating a process of forming a protective film on the wafer using the film deposition apparatus illustrated in FIG. 1;

FIG. 4 is a cross-sectional view of a wafer illustrating a process of etching the wafer illustrated in FIG. 3;

FIG. 5 is a cross-sectional view of a wafer illustrating a state in which the protective film is removed from the wafer illustrated in FIG. 4;

FIG. 6 is a chart illustrating another timing of supplying gas in the film deposition apparatus illustrated in FIG. 1;

FIG. 7 is a schematic view of a film deposition apparatus for evaluating the composition for film deposition according to the subject matter of this application;

FIG. 8 is a drawing illustrating a state in which a surface of a substrate deposited by using a composition for film deposition according to the embodiment is imaged by a light microscope dark field method, (a) is a state before heating and (b) is a state after heating; and

FIG. 9 is a drawing illustrating a state in which a surface of a substrate deposited by using a composition for film deposition of a comparative example is imaged by a light microscope dark field method, (a) is a state before heating and (b) is a state after heating.

### DESCRIPTION OF EMBODIMENTS

In the following, an embodiment of the present invention will be described in detail.

<Composition for Film Deposition>

A composition for film deposition according to the embodiment of the present invention includes a first component that polymerizes with a second component to form a nitrogen-containing carbonyl compound, and wherein a molecular structure of the first component and a molecular structure of the second component are asymmetric with each other.

<Nitrogen-Containing Carbonyl Compound>

In the composition for film deposition according to the embodiment, the nitrogen-containing carbonyl compound formed by polymerization of the first component and the second component is a polymer containing a carbon-oxygen double bond and nitrogen. The nitrogen-containing carbonyl compound constitutes a component of a film deposited by polymerization of the first component and the second component. The nitrogen-containing carbonyl compound can be, for example, a protective film for preventing a specific portion of a wafer from being etched, as a polymer film.

The nitrogen-containing carbonyl compound is not particularly limited. With respect to the stability of a formed film, examples of the nitrogen-containing carbonyl compound include polyureas, polyurethanes, polyamides, and polyimides. These nitrogen-containing carbonyl compounds may be used either singly or in combinations of two or more compounds. In the embodiment, among these nitrogen-containing carbonyl compounds, polyureas and polyimides are preferable, and polyureas are more preferable. Here, these nitrogen-containing carbonyl compounds are examples of the nitrogen-containing carbonyl compound in the composition for film deposition according to the subject matter of this application.

<First Component>

The first component included in the composition for film deposition according to the embodiment is a monomer that can polymerize with the second component to form the nitrogen-containing carbonyl compound. Compounds suitable as a first component are not particularly limited, but includes, for example, isocyanates, amines, acid anhydrides, carboxylic acids, and alcohols. These compounds are examples of suitable first components to be included in the composition for film deposition according to the subject matter of this application.

Isocyanates, which are examples of the first component, are a chemical species that can polymerize with amines to form polyureas and can polymerize with alcohols to form polyurethanes. The number of carbon atoms of the isocyanate is not particularly limited, but with respect to obtaining a sufficient film deposition rate, the number of carbon atoms is preferably 2 to 18, 2 to 12 more preferably, and 2 to 8 still more preferably.

Additionally, the structure of the isocyanate is not particularly limited, and for example, a basic structure of an aromatic compound, a xylene-based compound, an alicyclic compound, an aliphatic compound, and the like can be employed. Isocyanates including such a basic structure may be used either singly or in combinations of two or more compounds.

The functionality of the isocyanate is not particularly limited, but with respect to obtaining a sufficient film deposition rate, the isocyanate is preferably a monofunctional compound or a bifunctional compound.

Specific examples of suitable isocyanates include 4,4′-diphenylmethane diisocyanate, 1,3-bis(isocyanatomethyl)cyclohexane (H6XDI), 1,3-bis(isocyanatomethyl)benzene, paraphenylene diisocyanate (PPDI), 4,4′-methylene diisocyanate, benzyl isocyanate, 1,2-diisocyanatoethane, 1,4-diisocyanatobutane, 1,6-diisocyanatohexane, 1,8-diisocyanatooctane, 1,10-diisocyanatodecane, 1,6-diisocyanato-2,4,4-trimethylhexane, 1,2-diisocyanatopropane, 1,1-diisocyanatoethane, 1,3,5-triisocyanatobenzene, 1,3-bis(isocyanato-2-propyl)benzene, isophorone diisocyanate, and 2,5-bis(isocyanatomethyl)bicyclo[2.2.1]heptane. The above-described isocyanate compounds may be used either singly or in combinations of two or more compounds.

Amines, which are examples of the first component, are a chemical species that can polymerize with isocyanates to form polyureas, and also can polymerize with acid anhydrides to form polyimides. The number of carbon atoms of the amine is not particularly limited, but with respect to obtaining a sufficient deposition rate, the number of carbon atoms is preferably 2 to 18, more preferably 2 to 12, and still more preferably 4 to 12.

Additionally, the structure of the amine is not particularly limited, and, for example, a basic structure of an aromatic compound, a xylene-based compound, an alicyclic compound, an aliphatic compound, and the like can be employed. Amines including such a basic structure may be used either singly or in combinations of two or more compounds.

The functionality of the amine is not particularly limited, but with respect to obtaining a sufficient film deposition rate, the amine is preferably a monofunctional or bifunctional compound.

Specific examples of suitable amines include 1,3-bis(aminomethyl)cyclohexane (H6XDA), 1,3-bis(aminomethyl)benzene, paraxylylenediamine, 1,3-phenylenediamine (MPDA), paraphenylenediamine (PPDA), 4,4′-methylenedianiline (MDA), 3-(aminomethyl)benzylamine (MXDA), hexamethylenediamine(HMDA), benzylamine, 1,2-diaminoethane, 1,4-diaminobutane, 1,6-diaminohexane, 1,8-diaminooctane, 1,10-diaminodecan, 1,12-diaminododecan (DDA), 2-aminomethyl-1,3-propanediamine, methanetriamine, bicyclo[2.2.1]heptanedimethaneamine, piperazine, 2-methylpiperazine, 1,3-di-4-piperidylpropane, 1,4-diazepane, diethylenetriamine, N-(2-aminoethyl)-N-methyl-1,2-ethanediamine, bis(3-aminopropyl)amine, triethylenetetramine, and spermidine. The above-described amine compounds may be used either singly or in combinations of two or more compounds.

Acid anhydrides, which are examples of the first component, are a chemical species that can polymerize with amines to form polyimides. The number of carbon atoms of the acid anhydride is not particularly limited, but with respect to obtaining a sufficient film deposition rate, the number of carbon atoms is preferably 2 to 18, more preferably 2 to 12, and still more preferably 4 to 12.

The structure of the acid anhydride is not particularly limited, and for example, a basic structure of an aromatic compound, a xylene-based compound, an alicyclic compound, an aliphatic compound, and the like can be employed. Acid anhydrides including such a basic structure may be used either singly or in combinations of two or more compounds.

The functionality of the acid anhydride is not particularly limited, but with respect to obtaining a sufficient film deposition rate, the acid anhydride is preferably a monofunctional or bifunctional compound.

Specific examples of suitable acid anhydrides include pyromellitic dianhydride, 3,3′,4,4′-benzophenone tetracarboxylic dianhydride, 2,2′,3,3′-benzophenone tetracarboxylic dianhydride, 2,3,3′,4′-benzophenone tetracarboxylic dianhydride, naphthalene-1,2,5,6-tetracarboxylic dianhydride, naphthalene-1,2,4,5-tetracarboxylic dianhydride, naphthalene-1,4,5,8-tetracarboxylic dianhydride, naphthalene-1,2,6,7-tetracarboxylic dianhydride, 4,8-dimethyl-1,2,3,5,6,7-hexahydronaphthalene-1,2,5,6-tetracarboxylic dianhydride, 4,8-dimethyl-1,2,3,5,6,7-hexahydronaphthalene-2,3,6,7-tetracarboxylic dianhydride, 2,6-dichloronaphthalene-1,4,5,8-tetracarboxylic dianhydride, 2,7-dichloronaphthalene-1,4,5,8-tetracarboxylic dianhydride, 2,3,6,7-tetrachloronaphthalene-1,4,5,8-tetracarboxylic dianhydride, 1,4,5,8-tetrachloronaphthalene-2,3,6,7-tetracarboxylic dianhydride, 3,3′,4,4′-biphenyltetracarboxylic dianhydride, 2,2′,3,3′-biphenyltetracarboxylic dianhydride, 2,3,3′,4′-biphenyltetracarboxylic dianhydride, 3,3″,4,4″-p-terphenyltetracarboxylic dianhydride, 2,2″,3,3″-p-terphenyltetracarboxylic dianhydride, 2,3,3″,4″-p-terphenyltetracarboxylic dianhydride, 2,2-bis(2,3-dicarboxyphenyl)-propane dianhydride, 2,2-bis(3,4-dicarboxyphenyl)-propane dianhydride, bis(2,3-dicarboxyphenyl)ether dianhydride, bis(2,3-dicarboxyphenyl)methane dianhydride, bis(3,4-dicarboxyphenyl)methane dianhydride, bis(2,3-dicarboxyphenyl)sulfone dianhydride, bis(3,4-dicarboxyphenyl)sulfone dianhydride, 1,1-bis(2,3-dicarboxyphenyl)ethane dianhydride, 1,1-bis(3,4-dicarboxyphenyl)ethane dianhydride, perylene-2,3,8,9-tetracarboxylic dianhydride, perylene-3,4,9,10-tetracarboxylic dianhydride, perylene-4,5,10,11-tetracarboxylic dianhydride, perylene-5,6,11,12-tetracarboxylic dianhydride, phenanthrene-1,2,7,8-tetracarboxylic dianhydride, phenanthrene-1,2,6,7-tetracarboxylic dianhydride, phenanthrene-1,2,9,10-tetracarboxylic dianhydride, cyclopentane-1,2,3,4-tetracarboxylic dianhydride, pyrazine-2,3,5,6-tetracarboxylic dianhydride, pyrrolidine-2,3,4,5-tetracarboxylic dianhydride, thiophene-2,3,4,5-tetracarboxylic dianhydride, 4,4′-oxydiphthalic dianhydride, and 2,3,6,7-naphthalenetetracarboxylic dianhydride. The above-described acid anhydride compounds may be used either singly or in combinations of two or more compounds.

Carboxylic acids, which are examples of the first component, are a chemical species that can polymerize with amines to form polyamides. The number of carbon atoms of the carboxylic acid is not particularly limited, but with respect to obtaining a sufficient film deposition rate, the number of carbon atoms is preferably 2 to 18, is 2 to 12 more preferably, and is 2 to 8 still more preferably.

The structure of the carboxylic acid is not particularly limited, and for example, a basic structure of an aromatic compound, a xylene-based compound, an alicyclic compound, an aliphatic compound, and the like may be employed. Carboxylic acids including such a basic structure may be used either singly or in combinations of two or more compounds.

The functionality of the carboxylic acid is not particularly limited, but with respect to obtaining a sufficient film deposition rate, the carboxylic acid is preferably a monofunctional or bifunctional compound.

Specific examples of suitable carboxylic acids include butanedioic acid, pentanedioic acid, hexanedioic acid, octanedioic acid, 2,2′-(1,4-cyclohexanediyl)diacetic acid, 1,4-phenylenediacetic acid, 4,4′-methylenedibenzoic acid, phenyleneacetic acid, benzoic acid, salicylic acid, acetylsalicylic acid, succinyl chloride, glutaryl chloride, adipoyl chloride, suberoyl chloride, 2,2′-(1,4-phenylene) diacetyl chloride, terephthaloyl chloride, and phenylacetyl chloride. The above-described carboxylic acid compounds may be used either singly or in combinations of two or more compounds.

Alcohols, which are examples of the first component, are a chemical species that can polymerize with isocyanates to form polyurethanes. The number of carbon atoms of the alcohol is not particularly limited, but with respect to obtaining a sufficient film deposition rate, the number of carbon atoms is preferably 2 to 18, is more preferably 2 to 12, and is still more preferably 4 to 12.

The structure of the alcohol is not particularly limited, and for example, a basic structure of an aromatic compound, a xylene-based compound, an alicyclic compound, an aliphatic compound, and the like can be employed. Alcohols including such a basic structure may be used either singly or in combinations of two or more compounds.

The functionality of the alcohol is not particularly limited, but with respect to obtaining a sufficient film deposition rate, the alcohol is preferably a monofunctional or bifunctional compound.

Specific examples of suitable alcohols include 1,3-cyclohexanediyldimethanol, 1,3-phenylenedimethanol, hydroquinone, benzyl alcohol, 1,2-ethanediol, 1,4-butanediol, 1,6-hexanediol, 1,8-octanediol, 1,10-decanediol, 2,5-norbonandiol, methantriol, diethylene glycol, triethylene glycol, and 3,3′-oxydipropane-1-ol. The above-described alcohol compounds may be used either singly or in combinations of two or more compounds.

The desorption energy of the first component is the activation energy needed to remove the first component from an interface, and is expressed in the unit of kJ/mol. The range of the desorption energy of the first component is not particularly limited, but with respect to obtaining a sufficient film deposition rate, the range of the desorption energy of the first component is preferably 10 to 130 kJ/mol, is more preferably 30 to 120 kJ/mol, and is still more preferably 50 to 110 kJ/mol. If a minimum value of the range of the desorption energy is too low, the first component that does not contribute to polymerization is also adsorbed, and the purity of a formed polymer may be reduced. If a maximum value of the range of the desorption energy is too high, there is a possibility that a film of the nitrogen-containing carbonyl compound cannot be sufficiently formed or the uniformity of a formed film is reduced.

Another physical property of the first component is not particularly limited. To maintain adsorption of the first component, a boiling point of the first component is preferably 100° C. to 500° C. Specifically, the boiling point of the first component is 100° C. to 450° C. for amines, is 100° C. to 450° C. for isocyanates, is 120 to 500° C. for carboxylic acids, is 150° C. to 500° C. for acid anhydrides, and is 150° C. to 400° C. for alcohols.

<Second Component>

The second component included in the composition for film deposition according to the embodiment is a monomer that can polymerize with the first component to form the nitrogen-containing carbonyl compound. Compounds suitable as a second component are not particularly limited, but includes, for example, isocyanates, amines, acid anhydrides, carboxylic acids, and alcohols. These compounds are examples of suitable second components to be included in the composition for film deposition according to the subject matter of this application.

Isocyanates, which are examples of the second component, are a chemical species that can polymerize with amines to form polyureas and can polymerize with alcohols to form polyurethanes. The number of carbon atoms of the isocyanate is not particularly limited, but with respect to obtaining a sufficient film deposition rate, the number of carbon atoms is preferably 2 to 18, 2 to 12 more preferably, and 2 to 8 still more preferably.

Additionally, the structure of the isocyanate is not particularly limited, and for example, a basic structure of an aromatic compound, a xylene-based compound, an alicyclic compound, an aliphatic compound, and the like can be employed. Isocyanates including such a basic structure may be used either singly or in combinations of two or more compounds.

The functionality of the isocyanate is not particularly limited, but with respect to obtaining a sufficient film deposition rate, the isocyanate is preferably a monofunctional compound or a bifunctional compound.

Specific examples of suitable isocyanates include 4,4′-diphenylmethane diisocyanate, 1,3-bis(isocyanatomethyl)cyclohexane (H6XDI), 1,3-bis(isocyanatomethyl)benzene, paraphenylene diisocyanate (PPDI), 4,4′-methylene diisocyanate, benzyl isocyanate, 1,2-diisocyanatoethane, 1,4-diisocyanatobutane, 1,6-diisocyanatohexane, 1,8-diisocyanatooctane, 1,10-diisocyanatodecane, 1,6-diisocyanato-2,4,4-trimethylhexane, 1,2-diisocyanatopropane, 1,1-diisocyanatoethane, 1,3,5-triisocyanatobenzene, 1,3-bis(isocyanato-2-propyl)benzene, isophorone diisocyanate, and 2,5-bis(isocyanatomethyl)bicyclo[2.2.1]heptane. The above-described isocyanate compounds may be used either singly or in combinations of two or more compounds.

Amines, which are examples of the second component, are a chemical species that can polymerize with isocyanates to form polyureas, and also can polymerize with acid anhydrides to form polyimides. The number of carbon atoms of the amine is not particularly limited, but with respect to obtaining a sufficient deposition rate, the number of carbon atoms is preferably 2 to 18, more preferably 2 to 12, and still more preferably 4 to 12.

Additionally, the structure of the amine is not particularly limited, and, for example, a basic structure of an aromatic compound, a xylene-based compound, an alicyclic compound, an aliphatic compound, and the like can be employed. Amines including such a basic structure may be used either singly or in combinations of two or more compounds.

The functionality of the amine is not particularly limited, but with respect to obtaining a sufficient film deposition rate, the amine is preferably a monofunctional or bifunctional compound.

Specific examples of suitable amines include 1,3-bis(aminomethyl)cyclohexane (H6XDA), 1,3-bis(aminomethyl)benzene, paraxylylenediamine, 1,3-phenylenediamine (MPDA), paraphenylenediamine (PPDA), 4,4′-methylenedianiline (MDA), 3-(aminomethyl)benzylamine (MXDA), hexamethylenediamine (HMDA), benzylamine, 1,2-diaminoethane, 1,4-diaminobutane, 1,6-diaminohexane, 1,8-diaminooctane, 1,10-diaminodecan, 1,12-diaminododecan (DDA), 2-aminomethyl-1,3-propanediamine, methanetriamine, bicyclo[2.2.1]heptanedimethaneamine, piperazine, 2-methylpiperazine, 1,3-di-4-piperidylpropane, 1,4-diazepane, diethylenetriamine, N-(2-aminoethyl)-N-methyl-1,2-ethanediamine, bis(3-aminopropyl)amine, triethylenetetramine, and spermidine. The above-described amine compounds may be used either singly or in combinations of two or more compounds.

Acid anhydrides, which are examples of the second component, are a chemical species that can polymerize with amines to form polyimides. The number of carbon atoms of the acid anhydride is not particularly limited, but with respect to obtaining a sufficient film deposition rate, the number of carbon atoms is preferably 2 to 18, more preferably 2 to 12, and still more preferably 4 to 12.

The structure of the acid anhydride is not particularly limited, and for example, a basic structure of an aromatic compound, a xylene-based compound, an alicyclic compound, an aliphatic compound, and the like can be employed. Acid anhydrides including such a basic structure may be used either singly or in combinations of two or more compounds.

The functionality of the acid anhydride is not particularly limited, but with respect to obtaining a sufficient film deposition rate, the acid anhydride is preferably a monofunctional or bifunctional compound.

Specific examples of suitable acid anhydrides include pyromellitic dianhydride, 3,3′,4,4′-benzophenone tetracarboxylic dianhydride, 2,2′,3,3′-benzophenone tetracarboxylic dianhydride, 2,3,3′,4′-benzophenone tetracarboxylic dianhydride, naphthalene-1,2,5,6-tetracarboxylic dianhydride, naphthalene-1,2,4,5-tetracarboxylic dianhydride, naphthalene-1,4,5,8-tetracarboxylic dianhydride, naphthalene-1,2,6,7-tetracarboxylic dianhydride, 4,8-dimethyl-1,2,3,5,6,7-hexahydronaphthalene-1,2,5,6-tetracarboxylic dianhydride, 4,8-dimethyl-1,2,3,5,6,7-hexahydronaphthalene-2,3,6,7-tetracarboxylic dianhydride, 2,6-dichloronaphthalene-1,4,5,8-tetracarboxylic dianhydride, 2,7-dichloronaphthalene-1,4,5,8-tetracarboxylic dianhydride, 2,3,6,7-tetrachloronaphthalene-1,4,5,8-tetracarboxylic dianhydride, 1,4,5,8-tetrachloronaphthalene-2,3,6,7-tetracarboxylic dianhydride, 3,3′,4,4′-biphenyltetracarboxylic dianhydride, 2,2′,3,3′-biphenyltetracarboxylic dianhydride, 2,3,3′,4′-biphenyltetracarboxylic dianhydride, 3,3″,4,4″-p-terphenyltetracarboxylic dianhydride, 2,2″,3,3″-p-terphenyltetracarboxylic dianhydride, 2,3,3″,4″-p-terphenyltetracarboxylic dianhydride, 2,2-bis(2,3-dicarboxyphenyl)-propane dianhydride, 2,2-bis(3,4-dicarboxyphenyl)-propane dianhydride, bis(2,3-dicarboxyphenyl)ether dianhydride, bis(2,3-dicarboxyphenyl)methane dianhydride, bis(3,4-dicarboxyphenyl)methane dianhydride, bis(2,3-dicarboxyphenyl)sulfone dianhydride, bis(3,4-dicarboxyphenyl)sulfone dianhydride, 1,1-bis(2,3-dicarboxyphenyl)ethane dianhydride, 1,1-bis(3,4-dicarboxyphenyl) ethane dianhydride, perylene-2,3,8,9-tetracarboxylic dianhydride, perylene-3,4,9,10-tetracarboxylic dianhydride, perylene-4,5,10,11-tetracarboxylic dianhydride, perylene-5,6,11,12-tetracarboxylic dianhydride, phenanthrene-1,2,7,8-tetracarboxylic dianhydride, phenanthrene-1,2,6,7-tetracarboxylic dianhydride, phenanthrene-1,2,9,10-tetracarboxylic dianhydride, cyclopentane-1,2,3,4-tetracarboxylic dianhydride, pyrazine-2,3,5,6-tetracarboxylic dianhydride, pyrrolidine-2,3,4,5-tetracarboxylic dianhydride, thiophene-2,3,4,5-tetracarboxylic dianhydride, 4,4′-oxydiphthalic dianhydride, and 2,3,6,7-naphthalenetetracarboxylic dianhydride. The above-described acid anhydride compounds may be used either singly or in combinations of two or more compounds.

Carboxylic acids, which are examples of the second component, are a chemical species that can polymerize with amines to form polyamides. The number of carbon atoms of the carboxylic acid is not particularly limited, but with respect to obtaining a sufficient film deposition rate, the number of carbon atoms is preferably 2 to 18, is 2 to 12 more preferably, and is 2 to 8 still more preferably.

The structure of the carboxylic acid is not particularly limited, and for example, a basic structure of an aromatic compound, a xylene-based compound, an alicyclic compound, an aliphatic compound, and the like may be employed. Carboxylic acids including such a basic structure may be used either singly or in combinations of two or more compounds.

The functionality of the carboxylic acid is not particularly limited, but with respect to obtaining a sufficient film deposition rate, the carboxylic acid is preferably a monofunctional or bifunctional compound.

Specific examples of suitable carboxylic acids include butanedioic acid, pentanedioic acid, hexanedioic acid, octanedioic acid, 2,2′-(1,4-cyclohexanediyl)diacetic acid, 1,4-phenylenediacetic acid, 4,4′-methylenedibenzoic acid, phenyleneacetic acid, benzoic acid, salicylic acid, acetylsalicylic acid, succinyl chloride, glutaryl chloride, adipoyl chloride, suberoyl chloride, 2,2′-(1,4-phenylene)diacetyl chloride, terephthaloyl chloride, and phenylacetyl chloride. The above-described carboxylic acid compounds may be used either singly or in combinations of two or more compounds.

Alcohols, which are examples of the second component, are a chemical species that can polymerize with isocyanates to form polyurethanes. The number of carbon atoms of the alcohol is not particularly limited, but with respect to obtaining a sufficient film deposition rate, the number of carbon atoms is preferably 2 to 18, is more preferably 2 to 12, and is still more preferably 4 to 12.

The structure of the alcohol is not particularly limited, and for example, a basic structure of an aromatic compound, a xylene-based compound, an alicyclic compound, an aliphatic compound, and the like can be employed. Alcohols including such a basic structure may be used either singly or in combinations of two or more compounds.

The functionality of the alcohol is not particularly limited, but with respect to obtaining a sufficient film deposition rate, the alcohol is preferably a monofunctional or bifunctional compound.

Specific examples of suitable alcohols include 1,3-cyclohexanediyldimethanol, 1,3-phenylenedimethanol, hydroquinone, benzyl alcohol, 1,2-ethanediol, 1,4-butanediol, 1,6-hexanediol, 1,8-octanediol, 1,10-decanediol, 2,5-norbonandiol, methantriol, diethylene glycol, triethylene glycol, and 3,3′-oxydipropane-1-ol. The above-described alcohol compounds may be used either singly or in combinations of two or more compounds.

The desorption energy of the second component is the activation energy needed to remove the second component from an interface, and is expressed in the unit of kJ/mol. The range of the desorption energy of the second component is not particularly limited, but with respect to obtaining a sufficient film deposition rate, the range of the desorption energy of the second component is preferably 10 to 130 kJ/mol, is more preferably 30 to 120 kJ/mol, and is still more preferably 50 to 110 kJ/mol. If a minimum value of the range of the desorption energy is too low, the second component that does not contribute to polymerization is also adsorbed, and the purity of a formed polymer may be reduced. If a maximum value of the range of the desorption energy is too high, there is a possibility that a film of the nitrogen-containing carbonyl compound cannot be sufficiently formed or the uniformity of a formed film is reduced.

Another physical property of the second component is not particularly limited. To maintain adsorption of the second component, a boiling point of the second component is preferably 100° C. to 500° C. Specifically, the boiling point of the second component is 100° C. to 450° C. for amines, is 100° C. to 450° C. for isocyanate, is 120° C. to 500° C. for carboxylic acids, is 150° C. to 500° C. for acid anhydrides, and is 150° C. to 400° C. for an alcohols.

The combination of the first component and the second component is not particularly limited, but either the first component or the second component is preferably isocyanate, and the isocyanate is more preferably a bifunctional alicyclic compound. Still more preferably, the bifunctional alicyclic compound is 1,3-bis(isocyanatomethyl)cyclohexane (H6XDI).

Additionally, the other component of the first component or the second component is preferably amine, and the amine is more preferably a bifunctional alicyclic compound. Still more preferably, the bifunctional alicyclic compound is 1,3-bis(aminomethyl)cyclohexane (H6XDA).

A method of polymerizing the first component and the second component is not particularly limited as long as a nitrogen-containing carbonyl compound can be formed. However, with respect to obtaining a sufficient film deposition rate, a vapor deposition polymerization method is preferred. The vapor deposition polymerization method is a method of polymerization in which two or more monomers are simultaneously heated and evaporated in a vacuum so that the monomers are polymerized on a substrate.

The polymerization temperature is the temperature required for polymerization of the first component and the second component. The polymerization temperature is not particularly limited and may be adjusted based on a type of a nitrogen-containing carbonyl compound to be formed, and the specific first component and second component to be polymerized, for example. The polymerization temperature is indicated by temperature of the substrate for example when the first component and the second component are vapor-deposited and polymerized on the substrate. The specific polymerization temperature, for example, is 20° C. to 200° C. when polyureas are formed as a nitrogen-containing carbonyl compound, is 100° C. to 300° C. when polyimides are formed as a nitrogen-containing carbonyl compound, and is more preferably 38° C. to 150° C. when polyimides are formed as a nitrogen-containing carbonyl compound.

In the embodiment, the molecular structure of the first component and the molecular structure of the second component are asymmetric with each other. Here, a description that the molecular structures are asymmetric with each other indicates that basic skeletons of two molecules, excluding a substituent or a functional group, do not have point symmetry, line symmetry, plane symmetry, or rotational symmetry. For example, if the two molecules are a cyclic compound and a stranded compound, aromatic compounds with different orientations, and alicyclic compounds with cis-trans isomers (also called geometric isomers), the molecular structures of the two molecules are asymmetric with each other.

In this embodiment, the asymmetry between the molecular structure of the first component and the molecular structure of the second component reduces the occurrence of crystalline aggregation in a polymer as a polymer of the nitrogen-containing carbonyl compound grows by the film deposition process. Additionally, the occurrence of crystallites in a film due to heat treatment after film deposition is also reduced. Therefore, in the embodiment, the occurrence of crystallization in a film can be suppressed, and the occurrence of film roughness and structural defects can be prevented.

<Film Deposition Apparatus>

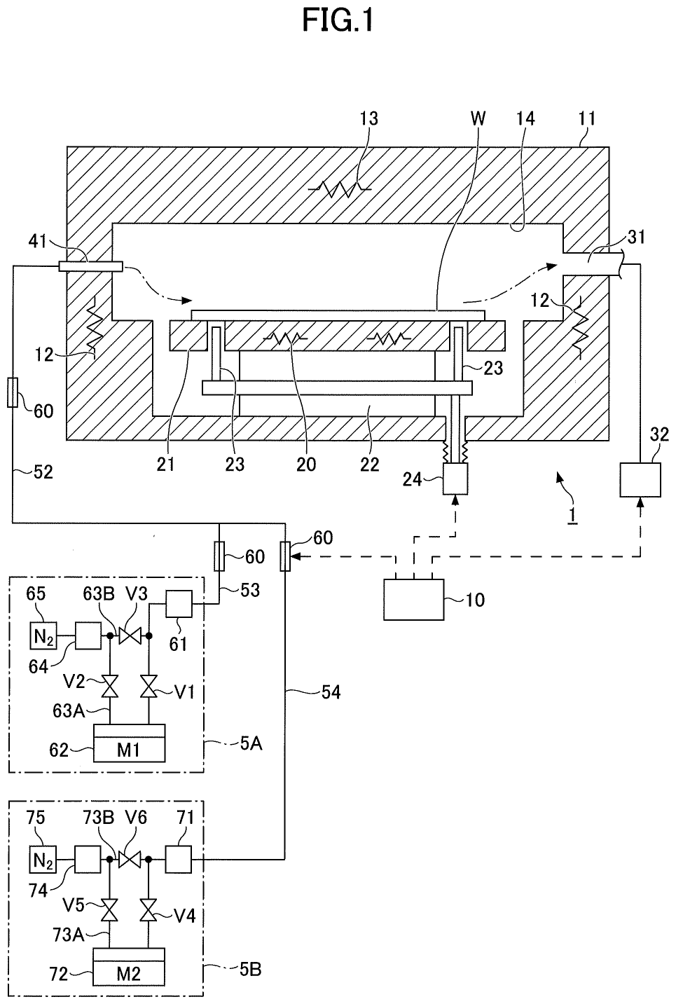

Next, a film deposition apparatus 1 according to the embodiment of the present invention will be described with reference to a cross-sectional view illustrated in FIG. 1. The film deposition apparatus 1 according to the embodiment includes a treatment vessel 11 in which a vacuum atmosphere is created, a pedestal (i.e., a stage 21) on which a substrate (i.e., a wafer W) is placed, provided in the treatment vessel 11, and a supply (i.e., a gas nozzle 41) for supplying the above-described composition for film deposition (i.e., a film deposition gas) into the treatment vessel 11. Here, the film deposition apparatus 1 is an example of a film deposition apparatus according to the subject matter of this application.

The treatment vessel 11 is configured as a circular shape and an airtight vacuum vessel to create a vacuum atmosphere inside. A side wall heater 12 is provided in a side wall of the treatment vessel 11. A ceiling heater 13 is provided in a ceiling (i.e., a top board) of the treatment vessel 11. A ceiling surface 14 of the ceiling (i.e., the top board) of the treatment vessel 11 is formed as a horizontal flat surface and the temperature of the ceiling surface 14 is controlled by the ceiling heater 13. Here, when the film deposition gas that can form a film at a relatively low temperature is used, the heat by the side wall heater 12 or the ceiling heater 13 is not necessary.

The stage 21 is provided at a lower side of the treatment vessel 11. The stage 21 constitutes the pedestal on which the substrate (i.e., the wafer W) is placed. The stage 21 is formed as a circular shape and the wafer W is placed on a horizontally formed surface (i.e., a top surface). Here, the substrate is not limited to the wafer W, and alternatively a glass substrate for manufacturing a flat panel display may be processed.

A stage heater 20 is embedded in the stage 21. The stage heater 20 heats a placed wafer W so that a protective film can be formed on the wafer W placed on the stage 21. Here, when the film deposition gas that can form a film at a relatively low temperature is used, it is not necessary to heat the placed wafer W by the stage heater 20.

The stage 21 is supported by the treatment vessel 11 through a support column 22 provided on a bottom surface of the treatment vessel 11. Lift pins 23 that are vertically moved are provided at positions outside of the periphery of the support column 22 in a circumferential direction. The lift pins 23 are inserted into respective through-holes provided at intervals in a circumferential direction of the stage 21. In FIG. 1, two out of three lift pins 23 that are provided, are illustrated. The lift pins 23 are controlled and moved up and down by a lifting mechanism 24. When the lifting pin 23 protrudes and recedes from a surface of the stage 21, the wafer W is transferred between a conveying mechanism (which is not illustrated) and the stage 21.

An exhaust port 31, which is opened, provided in the side wall of the treatment vessel 11. The exhaust port 31 is connected to an exhaust mechanism 32. The exhaust mechanism 32 is constituted by a vacuum pump, a valve, and so on with an exhaust pipe to adjust an exhaust flow rate from the exhaust port 31. Adjusting the exhaust flow rate by the exhaust mechanism 32 controls pressure in the treatment vessel 11. Here, a transfer port of the wafer W, which is not illustrated, is formed to be able to open and close at a position different from the position where the exhaust port 31 is opened in the side wall of the treatment vessel 11.

The gas nozzle 41 is also provided in the side wall of the treatment vessel 11. The gas nozzle 41 supplies the film deposition gas that includes the composition for film deposition described above into the treatment vessel 11. The composition for film deposition contained in the film deposition gas includes a first component M1 and a second component M2. The first component M1 is included in a first film deposition gas, the second component M2 is included in a second film deposition gas, and the first component M1 and the second component M2 are supplied into the treatment vessel 11.

The first component M1 included in the first film deposition gas is a monomer that can polymerize with the second component M2 to form a nitrogen-containing carbonyl compound. In the embodiment, 1,3-bis(isocyanatomethyl)cyclohexane (hereinafter referred to as H6XDI), which is a bifunctional alicyclic isocyanate, is used as the first component M1. Here, the first component M1 is not limited to H6XDI, and may be any compound that is suitable for use as the first component of the above-described composition for film deposition.

The second component M2 included in the second film deposition gas is a monomer that can polymerize with the first component M1 to form a nitrogen-containing carbonyl compound. In the embodiment, 1,3-bis(aminomethyl)cyclohexane (which will be hereinafter referred to as H6XDA) that is a two-functional alicyclic amine is used as the second component M2. Here, the second component M2 is not limited to H6XDA, and may be any compound that is suitable for use as the second component of the above-described composition for film deposition.

The gas nozzle 41 constitutes the supply (i.e., a film deposition gas supply) to supply the film deposition gas (i.e., the first film deposition gas and the second film deposition gas) for forming the protective film described above. The gas nozzle 41 is provided in the side wall of the treatment vessel 11 on a side opposite to the exhaust port 31 as viewed from the center of the stage 21.

The gas nozzle 41 is formed to project from the side wall of the treatment vessel 11 toward the center of the treatment vessel 11. An end of the gas nozzle 41 horizontally extends from the side wall of the treatment vessel 11. The film deposition gas is discharged from a discharging port opened at the end of the gas nozzle 41 into the treatment vessel 11, flows in a direction of an arrow of a dashed line illustrated in FIG. 1, and is exhausted from the exhaust port 31. Here, the end of the gas nozzle 41 is not limited to this shape. To increase the efficiency of film deposition, the end of the gas nozzle 41 may be extending obliquely downward toward the placed wafer W or extending obliquely upward toward the ceiling surface 14 of the treatment vessel 11.

When the end of the gas nozzle 41 is shaped to extend obliquely upward toward the ceiling surface 14 of the treatment vessel 11, the discharged film deposition gas collides with the ceiling surface 14 of the treatment vessel 11 before being supplied to the wafer W. An area where the gas collides with the ceiling surface 14 is, for example, at a position closer to the discharging port of the gas nozzle 41 than the center of the stage 21 and is near an end of the wafer W in a planar view.

As described, the film deposition gas collides with the ceiling surface 14 and is supplied to the wafer W, so that the film deposition gas discharged from the gas nozzle 41 travels a greater distance to reach the wafer W than the film deposition gas travels when the film deposition gas is directly supplied from the gas nozzle 41 toward the wafer W. When a distance in which the film deposition gas travels in the treatment vessel 11 increases, the film deposition gas diffuses laterally and is supplied with high uniformity in a surface of the wafer W.

The exhaust port 31 is not limited to a configuration in which the exhaust port 31 is provided in the side wall of the treatment vessel 11 as described above. The exhaust port 31 may be provided in the bottom surface of the treatment vessel 11. Additionally, the gas nozzle 41 is not limited to a configuration in which the gas nozzle 41 is provided in the side wall of the treatment vessel 11 as described above. The gas nozzle 41 may be provided in the ceiling of the treatment vessel 11. Here, it is preferable that an exhaust port 31 and a gas nozzle 41 are provided in the side wall of the treatment vessel 11 as described above in order to form an air flow of the film deposition gas so that the film deposition gas flows from one end to the other end of the surface of the wafer W and film deposition is performed on the wafer W with high uniformity.

The temperature of the film deposition gas discharged from the gas nozzle 41 is selectable, but the temperature observed until the film deposition gas is supplied to the gas nozzle 41 is preferably higher than the temperature in the treatment vessel 11 in order to prevent the film deposition gas from condensing in a flow path before the film deposition gas is supplied to the gas nozzle 41. In this case, the film deposition gas cools upon being discharged into the treatment vessel 11 and is supplied to the wafer W. The wafer W then adsorbs the film deposition gas being supplied to the treatment vessel 11 with the decrease in the temperature of the film deposition gas, adsorption of the film deposition gas for the wafer W becomes high, and the film deposition proceeds efficiently. Additionally, with respect to further increasing the adsorption of the film deposition gas for the wafer W, it is preferable that the temperature in the treatment vessel 11 is higher than the temperature of the wafer W (or the temperature of the stage 21 in which the stage heater 20 is embedded).

The film deposition apparatus 1 includes a gas supply pipe 52 connected to the gas nozzle 41 from the outside of the treatment vessel 11. The gas supply pipe 52 includes gas introduction pipes 53 and 54 branched at an upstream side. An upstream side of a gas introduction pipe 53 is connected to a vaporizing part 62 through a flow adjustment part 61 and a valve V1 in the indicated order.

In the vaporizing part 62, the first component M1 (H6XDI) is stored in a liquid state. The vaporizing part 62 includes a heater (which is not illustrated) for heating the H6XDI. One end of a gas supply pipe 63A is connected to the vaporizing part 62, and the other end of the gas supply pipe 63A is connected to an N2 (nitrogen) gas supply source 65 through a valve V2 and a gas heater 64 in the indicated order. With such a configuration, heated N2 gas is supplied to the vaporizing part 62, H6XDI in the vaporizing part 62 is vaporized, and mixed gas of the N2 gas used for vaporizing and H6XDI gas can be introduced to the gas nozzle 41 as the first film deposition gas.

The gas supply pipe 63A branches to form a gas supply pipe 63B at a position in a downstream direction from the gas heater 64 and in an upstream direction from the valve V2. A downstream end of the gas supply pipe 63B is connected to the gas introduction pipe 53 at a position in a downstream direction from the valve V1 and in an upstream direction from the flow adjustment part 61 through a valve V3. With such a configuration, when the first film deposition gas described above is not supplied to the gas nozzle 41, the N2 gas heated by the gas heater 64 is introduced to the gas nozzle 41 without going through the vaporizing part 62.

In FIG. 1, a first film deposition gas supply mechanism 5A includes the flow adjustment part 61, the vaporizing part 62, the gas heater 64, the N2 gas supply source 65, the valves V1 to V3, the gas supply pipes 63A and 63B, and a portion of the gas introduction pipe 53 at an upstream side of the flow adjustment part 61.

An upstream side of a gas introduction pipe 54 is connected to a vaporizing part 72 through a flow adjustment part 71 and a valve V4 in the indicated order. In the vaporizing part 72, the second component M2 (H6XDA) is stored in a liquid state. The vaporizing part 72 includes a heater (which is not illustrated) to heat the H6XDA. One end of a gas supply pipe 73A is connected to the vaporizing part 72, and the other end of the gas supply pipe 73A is connected to an N2 (nitrogen) gas supply source 75 through a valve V5 and a gas heater 74 in the indicated order. With such a configuration, heated N2 gas is supplied to the vaporizing part 72, H6XDA in the vaporizing part 72 is vaporized, and mixed gas of the N2 gas used for vaporizing and H6XDA gas can be introduced to the gas nozzle 41 as the second film deposition gas.

The gas supply pipe 73A branches to form a gas supply pipe 73B at a position in a downstream direction from the gas heater 74 and in an upstream direction from the valve V5. A downstream end of the gas supply pipe 73B is connected to the gas introduction pipe 54 at a position in a downstream direction from the valve V4 and in an upstream direction from the flow adjustment part 71 through a valve V6. With such a configuration, when the second film deposition gas described above is not supplied to the gas nozzle 41, the N2 gas heated by the gas heater 74 is introduced to the gas nozzle 41 without going through the vaporizing part 72.

In FIG. 1, a second film deposition gas supply mechanism 5B includes the flow adjustment part 71, the vaporizing part 72, the gas heater 74, the N2 gas supply source 75, the valves V4 to V6, the gas supply pipes 73A and 73B, and a portion of the gas introduction pipe 54 at an upstream side of the flow adjustment part 71, described above.

For the gas supply pipe 52 and the gas introduction pipes 53 and 54, a pipe heater 60, for example, is provided around each of the pipes to heat the inside of a corresponding pipe to prevent H6XDI and H6XDA in the flowing film deposition gas from condensing. The pipe heater 60 adjusts the temperature of the film deposition gas to be discharged from the gas nozzle 41. In the embodiment, for convenience of illustration, the pipe heater 60 is illustrated only in a part of the pipe, but the pipe heater 60 is provided over the entire length of the pipe to prevent condensation.

When gas supplied from the gas nozzle 41 into the treatment vessel 11 is simply described as N2 gas, the gas indicates N2 gas alone supplied without going through the vaporizing parts 62 and 72 (i.e., bypassed) as described above, and is distinguished from N2 gas contained in the film deposition gas.

The gas introduction pipes 53 and 54 are not limited to the configuration in which the gas supply pipe 52 connected to the gas nozzle 41 branches. The gas introduction pipes 53 and 54 may be configured as separate gas nozzles that respectively supply the first film deposition gas and the second film deposition gas into the treatment vessel 11. This configuration can prevent the first film deposition gas and the second film deposition gas from reacting with each other and forming a film in a flow path before being supplied into the treatment vessel 11.

The film deposition apparatus 1 includes a controller 10 that is a computer, and the controller 10 includes a program, a memory, and a CPU. The program includes an instruction (each step) to proceed processing for the wafer W, which will be described later. The program is stored in a computer storage medium such as a compact disk, a hard disk, a magneto-optical disk, and a DVD, and installed in the controller 10. The controller 10 outputs a control signal to each part of the film deposition apparatus 1 by the program and the controller 10 controls an operation of each part. Specifically, operations such as control of an exhaust flow rate by the exhaust mechanism 32, control of a flow rate of each gas supplied into the treatment vessel 11 by the flow adjustment parts 61 and 71, control of an N2 gas supply from the N2 gas supply sources 65 and 75, control of power supply to each heater, and control of the lift pins 23 by the lifting mechanism 24 are controlled by the control signal.

In the film deposition apparatus 1, with the configuration described above, the composition for film deposition that includes the first component M1 and the second component M2 is supplied into the treatment vessel 11, and the first component M1 and the second component M2 are polymerized to form a nitrogen-containing carbonyl compound. In the embodiment, polymerization of the first component M1 (H6XDI) and the second component M2 (H6XDA) forms a polymer (polyurea) containing a urea bond as a nitrogen-containing carbonyl compound.

The nitrogen-containing carbonyl compound is deposited as a polymer film on the wafer W by the first film deposition gas and the second film deposition gas being vapor-deposited and polymerized on the surface of the wafer W. The polymer film that is formed of a nitrogen-containing carbonyl compound can be a protective film that prevents a specific portion of the wafer W from being etched for example, as described below.

Here, the cis and trans isomers are present in H6XDI constituting the first component M1 included in the first film deposition gas. Thus, the molecular structure of H6XDI contains cis isomers and trans isomers in a constant ratio. Additionally, the cis and trans isomers are also present in H6XDA that constitutes the second component M2 included in the second film deposition gas. Thus, the molecular structure of H6XDA contains cis isomers and trans isomers in a constant ratio.

Accordingly, in the film deposition apparatus 1, the molecular structure of the first component M1 (H6XDI) included in the first film deposition gas supplied into the treatment vessel 11 and the molecular structure of the second component M2 (H6XDA) included in the second deposition gas are asymmetric with each other. Therefore, in the film deposition process using the film deposition apparatus 1, the occurrence of crystallization in a film can be suppressed, and the occurrence of film roughness and structural defects can be prevented.

In the embodiment, cis isomers and trans isomers are present in both the first component M1 and the second component M2. However, a mixture of cis isomers and trans isomers may be present in only one of either the first component M1 or the second component M2 so that the molecular structure of the first component M1 and the molecular structure of the second component M2 are asymmetric.

Additionally, a case in which the molecular structure of the first component M1 and the molecular structure of the second component M2 are asymmetric, is not limited to the case in which either the first component M1 or the second component M2 contains cis-trans isomers as described above. For example, the molecular structure of the first component M1 and the molecular structure of the second component M2 are asymmetric with each other in a case of a cyclic compound and a chain compound, aromatic compounds with different orientations, and the like.

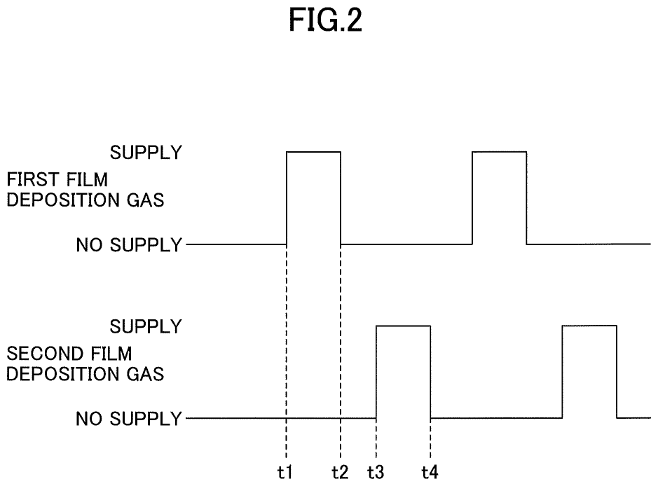

Next, a process performed on the wafer W using the film deposition apparatus 1 described above will be described with reference to FIG. 2. FIG. 2 is a timing chart illustrating duration of time in which each gas is supplied. In the film deposition apparatus 1, the wafer W is conveyed into the treatment vessel 11 by a conveying mechanism which is not illustrated and is transferred to the stage 21 through the lift pins 23. The side wall heater 12, the ceiling heater 13, the stage heater 20, and the pipe heater 60 are each heated to a predetermined temperature. Additionally, the inside of the treatment vessel 11 is adjusted to a vacuum atmosphere of a predetermined pressure.

The first film deposition gas that includes H6XDI is supplied from the first film deposition gas supply mechanism 5A to the gas nozzle 41 and the N2 gas is supplied from the second film deposition gas supply mechanism 5B to the gas nozzle 41. These are mixed to be at 140° C. and discharged from the gas nozzle 41 into the treatment vessel 11 (see FIG. 2 and time t1). The mixed gas is cooled down to 100° C. in the treatment vessel 11, is flowed through the treatment vessel 11 and is supplied to the wafer W. The mixed gas is further cooled on the wafer W to 80° C. and the first film deposition gas in the mixed gas is adsorbed on the wafer W.

Subsequently, the N2 gas is supplied from the first film deposition gas supply mechanism 5A instead of the first film deposition gas, and only N2 gas is discharged from the gas nozzle 41 (time t2). The N2 gas operates as a purge gas and the first film deposition gas that is not adsorbed on the wafer W in the treatment vessel 11 is purged.

Subsequently, the second film deposition gas that includes B6XDA is supplied to the gas nozzle 41 from the second film deposition gas supply mechanism 5B. These are mixed to be at 140° C. and discharged from the gas nozzle 41 (time t3). The mixed gas including the second film deposition gas is cooled down in the treatment vessel 11, is flowed through the treatment vessel 11, is supplied to the wafer W, and is further cooled down on the wafer W surface, in a manner similar to the mixed gas that includes the first film deposition gas supplied into the treatment vessel 11 from the time t1 to the time t2. The second film deposition gas included in the mixed gas is adsorbed on the wafer W.

The adsorbed second film deposition gas polymerizes with the first film deposition gas already adsorbed on the wafer W, and a polyurea film is formed on the surface of the wafer W. Consequently, the N2 gas is supplied from the second film deposition gas supply mechanism 5B instead of the second film deposition gas, and only N2 gas is discharged from the gas nozzle 41 (time t4). The N2 gas operates as a purge gas to purge the second film deposition gas that is not adsorbed on the wafer W in the treatment vessel 11.

In a series of the processes described above, the gas nozzle 41 first discharges the mixed gas including the first film deposition gas, then discharges only the N2 gas, and finally discharges the mixed gas including the second film deposition gas. When this series of the processes is defined as one cycle, the cycle is repeated after the time t4, and the polyurea film thickness increases. When a predetermined number of cycles are performed, the discharge of gas from the gas nozzle 41 stops.

In the embodiment, the molecular structure of the first component M1 (H6XDI) included in the first film deposition gas and the molecular structure of the second component M2 (H6XDA) included in the second film deposition gas are asymmetric with each other. In the film deposition apparatus 1, because the first film deposition gas and the second film deposition gas are supplied to the wafer W in the treatment vessel 11, it is possible to obtain an effect similar to a case in which the composition for film deposition described above is used. That is, according to the film deposition apparatus 1 of the embodiment, the occurrence of crystallization in a film can be suppressed, and the occurrence of film roughness and structural defects can be prevented in a film deposition process.

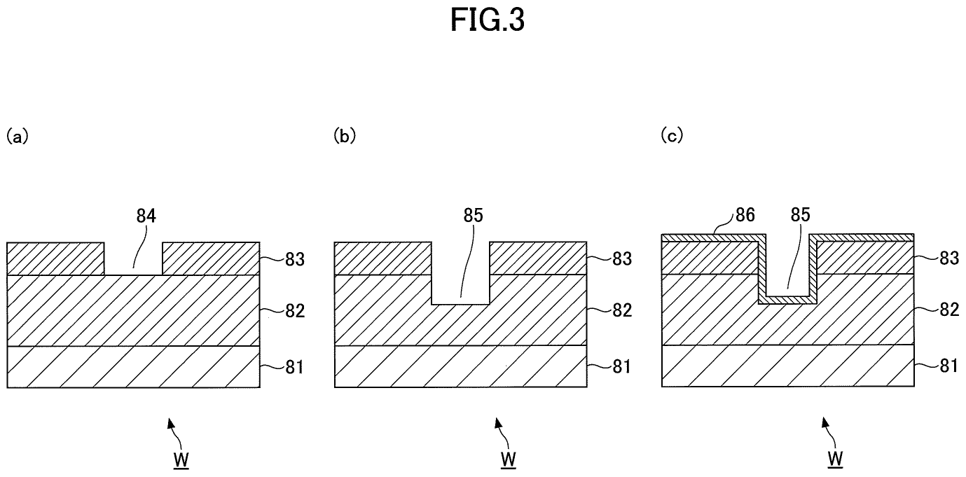

An example of a process performed using the film deposition apparatus 1 and an etching apparatus will be described. FIG. 3(a) illustrates a surface portion of the wafer W that is formed by stacking an underlayer film 81, an interlayer insulating film 82, and a hard mask film 83 in the order from the lower side to the upper side, and a pattern 84, which is an opening, is formed in the hard mask film 83. In etching the interlayer insulating film 82 through the pattern 84 to form a recess for embedding a wiring, the polyurea film described above is formed as a protective film so that a side wall of the recess is not damaged.

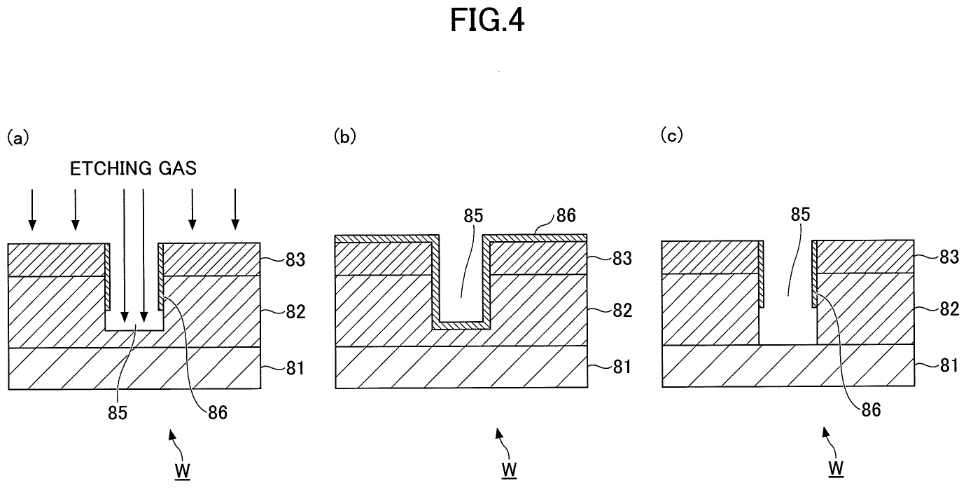

First, after a recess 85 is formed in the interlayer insulating film 82 by the etching apparatus (FIG. 3(b)), a polyurea film 86 is formed on the surface of the wafer W by the film deposition apparatus 1 described above. This coats the side wall and bottom of the recess 85 with the polyurea film 86 (FIG. 3(c)). Subsequently, the wafer W is conveyed to the etching apparatus and the depth of the recess 85 is increased by anisotropic etching. At this etching, the bottom of the recess 85 is etched in a state in which the polyurea film 86 is deposited on the side wall of the recess 85 and protects the side wall of the recess 85 (FIG. 4(a)). Next, the wafer W is conveyed to the film deposition apparatus 1 and a polyurea film 86 is newly formed on the surface of the wafer W (FIG. 4(b)). Next, the bottom of the recess 85 is etched again in a state in which the side wall of the recess 85 is protected by the polyurea film 86, and the etching ends when the underlayer film 81 is exposed (FIG. 4(c)). Subsequently, the hard mask film 83 and the polyurea film 86 are removed by dry etching or wet etching (FIG. 5).

As illustrated in FIG. 3 to FIG. 5, even when the etching apparatus is combined with the film deposition apparatus 1, the molecular structure of the first component M1 (H6XDI) included in the first film deposition gas and the molecular structure of the second component M2 (H6XDA) included in the second film deposition gas are asymmetric with each other. This can suppress the occurrence of crystallization in a film, and prevent the occurrence of film roughness and structural defects during a film deposition process. Therefore, this can improve throughput in a manufacturing process of a semiconductor device for example.

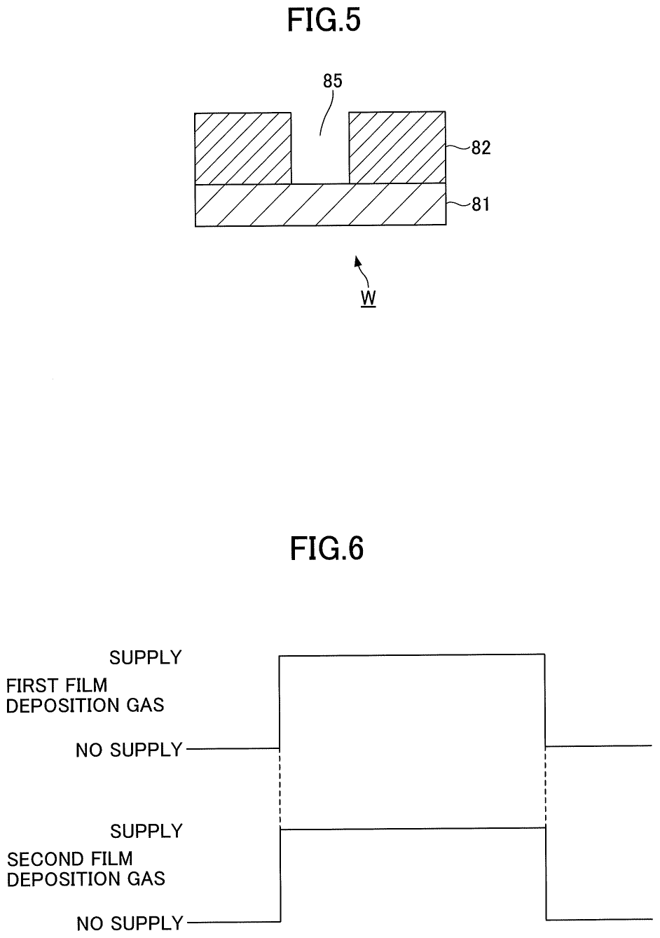

If the temperature of the first film deposition gas and the temperature of the second film deposition gas are relatively high, adsorption and film deposition on a surface tend to be difficult to occur. Thus, as illustrated in a timing chart of FIG. 6, the first film deposition gas and the second film deposition gas may be simultaneously supplied to the gas nozzle 41 and discharged from the gas nozzle 41 into the treatment vessel 11.

As illustrated in FIG. 6, even when the first film deposition gas and the second film deposition gas are simultaneously supplied to the gas nozzle 41, the molecular structure of the first component M1 (H6XDI) included in the first film deposition gas and the molecular structure of the second component M2 (H6XDA) included in the second film deposition gas are asymmetric with each other. Therefore, even when the first film deposition gas and the second film deposition gas are simultaneously supplied to the gas nozzle 41, the occurrence of crystallization in a film can be suppressed, and the occurrence of film roughness and structurals defect can be prevented in a film deposition process.

### EXAMPLES

In the following, the present invention will be described specifically with reference to examples. In the examples and a comparative example, measurement and evaluation were performed as follows.

[Film Deposition]

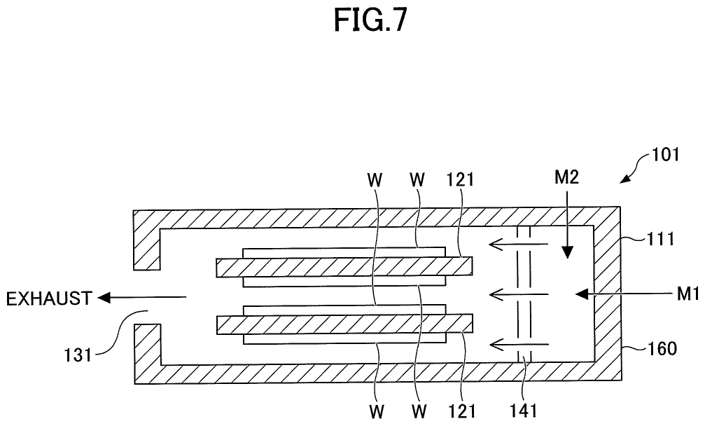

A film deposition apparatus 101 illustrated in FIG. 7 was used to form a polymer film. Here, in FIG. 7, the portion common to FIG. 1 is referred by a reference numeral generated by adding 100 to each reference numeral of FIG. 1 and a description is omitted. Specifically, the wafer W was placed in a treatment vessel 111, and a film deposition gas (the composition for film deposition that includes the first component M1 and the second component M2) was supplied to form a polymer film on the wafer W at room temperature. The film deposition was performed on four wafers W simultaneously. A 300 mm diameter silicon wafer was used for the wafer W.

[Heat Treatment]

A wafer W on which a polymer film is formed, is placed in a hot plate (which is not illustrated) of a nitrogen atmosphere and heated at 250° C. for 5 minutes.

[Dark Field Observation]

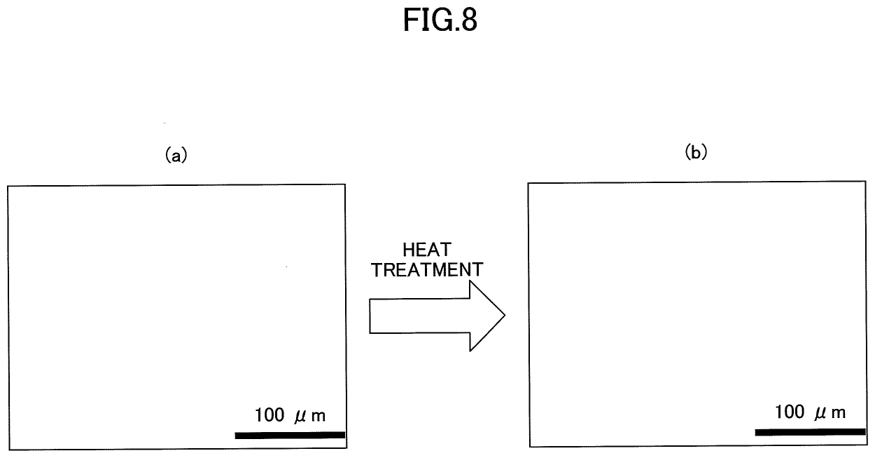

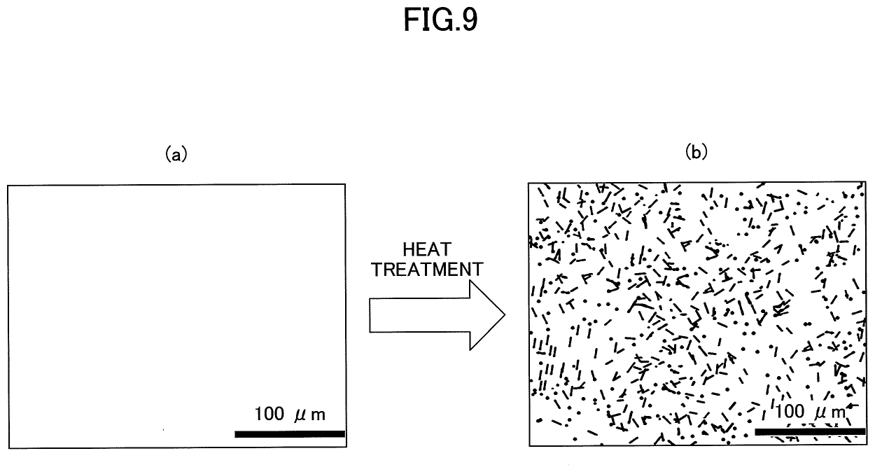

The surface of the polymer film deposited on the wafer W was observed before and after heat treatment in the dark field using an optical thin film and scatterometry (OCD) measuring device (which is a device named “n&k Analyzer” and manufactured by n&k Technology). When light scattering was observed by the dark field observation, it was evaluated that film roughness (crystallization) occurred. The evaluation was performed using pictures of the surface of the film imaged in the dark field (as illustrated in FIG. 8 and FIG. 9). In FIG. 8 and FIG. 9, a spotted area indicates light scattering, and a white area indicates no light scattering.

In the following, an example and a comparative example will be described.

### Example 1

1,3-bis(isocyanatomethyl)cyclohexane (H6XDI) was supplied as the first component M1, 1,3-bis(aminomethyl)cyclohexane (H6XDA) was supplied as the second component M2, and a polymer film is formed on the wafer W. Both H6XDI constituting the first component M1 and H6XDA constituting the second component M2 are compounds in which cis isomers and trans isomers are present. In Example 1, the surface of the film was evaluated before and after the heat treatment. The results are indicated in Table 1 and FIG. 8.

### Comparative Example 1

With the exception that 1,3-bis(isocyanatomethyl)benzene (XDI) was supplied instead of H6XDI as the first component M1, and 1,3-bis(aminomethyl)benzene (XDA) was supplied instead of H6XDA as the second component M2, the film was formed and evaluated in a manner similar to Example 1. Both XDI and XDA are meta-oriented aromatic compounds. The results are indicated in Table 1 and FIG. 9.

TABLE 1

| | | COMPARATIVE |
|---|---|---|
| | EXAMPLE | EXAMPLE |
| | 1 | 1 |
| FIRST COMPONENT M1 | H6XDI | XDI |
| SECOND COMPONENT M2 | H6XDA | XDA |
| LIGHT SCATTERING | NOT | NOT |
| (BEFORE HEAT | OBSERVED | OBSERVED |
| TREATMENT) | | |
| LIGHT SCATTERING | NOT | OBSERVED |
| (AFTER HEAT | OBSERVED | |
| TREATMENT) | | |

From Table 1, when the cis-trans isomer exists in the first component M1 (Example 1), light scattering was not observed before and after the heat treatment.

With respect to this, when both the first component M1 and the second component are aromatic compounds and have the same orientation in the basic structure (Comparative example 1), light scattering was observed after the heat treatment.

From these results, it has been found that film roughness (crystallization in a film) is suppressed. This can be achieved by performing the film deposition process using a composition for film deposition in which the molecular structures of the first component that polymerizes with the second component to form a nitrogen-containing carbonyl compound is asymmetric with each other.

Example embodiments of the present invention have been described in detail above, but the present invention is not limited to a specific embodiment. The various modifications and alterations may be made within the scope of the invention described in the claims.

This international application is based upon and claims the benefit of priority of the prior Japanese Patent Application No. 2018-108154, filed Jun. 5, 2018, the entire contents of which are incorporated herein by reference.

### DESCRIPTION OF REFERENCE SYMBOLS

W wafer
1 film deposition apparatus
11 treatment vessel
21 stage
20 stage heater
31 exhaust port
41 gas nozzle
60 pipe heater

1. A composition for film deposition comprising:
a first component; and
a second component,
wherein the second component polymerizes with the first component to form a nitrogen-containing carbonyl compound, and
wherein a molecular structure of the first component and a molecular structure of the second component are asymmetric with each other.

2. The composition for film deposition as claimed in claim 1, wherein the nitrogen-containing carbonyl compound is at least one compound selected from among a polyurea, a polyurethane, a polyamide, and a polyimide.

3. The composition for film deposition as claimed in claim 1, wherein at least one of the first component and the second component is any one of an isocyanate, an amine, an acid anhydride, a carboxylic acid, and an alcohol.

4. The composition for film deposition as claimed in claim 3, wherein at least one of the first component and the second component is at least one compound selected from among an aromatic compound, a xylene-based compound, an alicyclic compound, and an aliphatic compound.

5. The composition for film deposition as claimed in claim 3, wherein at least one of the first component and the second component is either a monofunctional compound or a bifunctional compound.

6. The composition for film deposition as claimed in claim 3, wherein one component of the first component and the second component is the isocyanate and another component of the first component and the second component is the amine.

7. The composition for film deposition as claimed in claim 6, wherein the isocyanate is a bifunctional alicyclic compound.

8. The composition for film deposition as claimed in claim 6, wherein the amine is a bifunctional alicyclic compound.

9. A film deposition apparatus comprising:
a treatment vessel in which a vacuum atmosphere is created;
a pedestal on which a substrate is placed, provided in the treatment vessel; and
a supply that supplies the composition for film deposition as claimed in claim 1 into the treatment vessel.

10. A method of manufacturing a semiconductor device, the method comprising the steps of:
(a) preparing a wafer formed by stacking a hard mask film in which a pattern is formed, an interlayer insulating film, and an underlayer film in order from an upper side to a lower side;
(b) forming a recess in the interlayer insulating film through the pattern;
(c) forming a protective film on a side wall and a bottom of the recess in the interlayer insulating film;
(d) etching the bottom of the recess in the interlayer insulating film; and
(e) repeating the step (c) and the step (d) until the underlayer film is exposed,
wherein the protective film is formed by a composition including a first component and a second component, wherein the second component polymerizes with the first component to form a nitrogen-containing carbonyl compound, and wherein a molecular structure of the first component and a molecular structure of the second component are asymmetric with each other.

11. The method as claimed in claim 10, further comprising:
(f) removing the hard mask film and the protective film after the step (e).

12. The method as claimed in claim 10, wherein the step (b) and the step (d) are performed by an etching apparatus, and the step (c) is performed by a film deposition apparatus.
